(19) United States
(12) Patent Application Publication
(10) Pub. No.: US 2025/0330133 A1
(43) Pub. Date: Oct. 23, 2025

(54) CIRCUITS AND METHODS FOR VARYING THE LINEARITY OF A LOW NOISE AMPLIFIER

(71) Applicant: Skyworks Solutions, Inc., Irvine, CA (US)

(72) Inventors: Sabah Khesbak, Irvine, CA (US); Peihua Ye, Irvine, CA (US); Thomas Obkircher, Santa Ana, CA (US); Mark Alan Richey, Carlsbad, CA (US)

(21) Appl. No.: 19/185,223

(22) Filed: Apr. 21, 2025

Related U.S. Application Data
(60) Provisional application No. 63/637,237, filed on Apr. 22, 2024.

(51) Int. Cl. H03F 3/195; H04B 1/40

(52) U.S. Cl. CPC H03F 3/195; H04B 1/40; H03F 2200/294

(57) ABSTRACT

A wireless device has an antenna and a radio frequency front-end including a variable low noise amplifier with a plurality of linearity configurations. The radio frequency front-end is configured to vary the linearity configuration corresponding to a variable status of a plurality of statuses of the wireless device.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of the invention relate to electronic systems, and in particular, to radio frequency (RF) electronics.

### Description of Related Technology

A low noise amplifier (LNA) can be used to boost the amplitude of a relatively weak radio frequency (RF) signal received via an antenna. Thereafter, the boosted RF signal can be used for a variety of purposes, including, for example, driving a switch, a mixer, and/or a filter in an RF communication system.

Examples of RF communication systems with one or more LNAs include, but are not limited to, mobile phones, tablets, base stations, network access points, customer-premises equipment (CPE), laptops, and wearable electronics.

LNAs can be included in RF communication systems to amplify signals of a wide range of frequencies. For example, an LNA can be used to provide low noise amplification to RF signals in a frequency range of about 30 KHz to 300 GHz, such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

The systems, methods, and devices of this disclosure each have several aspects, no single one of which is solely responsible for the desirable attributes disclosed herein.

The invention addresses the problem of the current consumption of a low noise amplifier (LNA) in an RF communication system providing a performance which may not be in line with the actual use of the device in which the RF communication system is implemented and/or may not be in line with device's environment because the environment affects said performance. Power consumption of an LNA may thus be higher than required in one situation while the LNA's performance may be lower than required in another situation.

For example, in applications of the Cellular Vehicle-to-Everything (CV2X) technology and/or the Global Navigation Satellite System GNSS technology for vehicles, a requirement for the vehicle's RF communication system's LNA may be to have a small current consumption even though the vehicle does have a large battery supply. The requirement arises from the storage and/or parking of the vehicle rather than its regular use. During the storage and/or parking of the vehicle over longer periods, the communication system's LNA may be requested to wake up for a certain period of time to check if there is any request for a communication connection.

With the elapse of time and with other devices drawing additional current, the total current drawn by the receive path, may result in a considerable amount of energy taken from a charged battery of the vehicle. In such situations, power consumption of the LNA may be reduced.

In another example situation, in order to have an adequate performance of the receive system during a normal receiving session when the vehicle is driving or only temporary parked, the linearity of the LNA should be adequate. Hence the input intercept point 3 (IIP3) of the LNA should be improved as compared to, e.g., the situation in which the vehicle is parked over longer periods of time. Therefore, the IIP3 of an LNA can be improved resulting in an increased power consumption of the LNA.

In a further example situation, a jammer may exist at a power level that affects the RF communication of the RF communication system having the LNA. To maintain the performance of the RF communication system, the linearity of the LNA should again be increased, resulting in an increased power consumption of the LNA.

While optimizations between current consumption and the system's linearity (i.e. the IIP3) have been suggested, implementations fall short on guaranteeing the required LNA linearity. Therefore, solutions are proposed to dynamically change the linearity of the RF communication system as required according to the use of the device and/or the device's environment.

In some aspects, the techniques described herein relate to a device including: an antenna; and a radio frequency front-end including a variable low noise amplifier in a linearity configuration of a plurality of linearity configurations for the variable low noise amplifier, the radio frequency front-end configured to vary the linearity configuration for the low noise amplifier corresponding to a variable status of a plurality of statuses of the device.

In some aspects, the techniques described herein relate to a device wherein the radio frequency front-end is configured to vary the linearity configuration for the low noise amplifier corresponding to the variable status of the plurality of statuses of the device by determining whether the device is in a first status or in a second status of the plurality of statuses for the device.

In some aspects, the techniques described herein relate to a device wherein the radio frequency front-end is configured to vary the linearity configuration for the low noise amplifier corresponding to the variable status of the plurality of statuses of the device by, in response to a determination that the device is in the first status, operating the variable low noise amplifier with a first linearity configuration for the variable low noise amplifier according to the first status of the device.

In some aspects, the techniques described herein relate to a device wherein the radio frequency front-end is configured to vary the linearity configuration for the low noise amplifier corresponding to the variable status of the plurality of statuses of the device by, in response to a determination that the device is in the second status, operating the variable low noise amplifier with a second linearity configuration for the variable low noise amplifier according to the second status of the device.

In some aspects, the techniques described herein relate to a device wherein the radio frequency front-end is configured to vary the linearity configuration for the low noise amplifier corresponding to the variable status of the plurality of statuses of the device by, in response to a determination that the device is in the second status, determining whether the device is in a third status or in a fourth status of the plurality of statuses for the device.

In some aspects, the techniques described herein relate to a device wherein the third status corresponds to a situation in which no jammer is present.

In some aspects, the techniques described herein relate to a device wherein the radio frequency front-end is configured to vary the linearity configuration for the low noise amplifier corresponding to the variable status of the plurality of statuses of the device by, in response to a determination that the device is in the third status, operating the variable low noise amplifier with a third linearity configuration for the variable low noise amplifier.

In some aspects, the techniques described herein relate to a device wherein the second linearity configuration for the variable low noise amplifier and the third linearity configuration for the variable low noise amplifier are the same linearity configurations.

In some aspects, the techniques described herein relate to a device wherein the second linearity configuration for the variable low noise amplifier and the third linearity configuration for the variable low noise amplifier are the same linearity configurations.

In some aspects, the techniques described herein relate to a device wherein the radio frequency front-end is configured to vary the linearity configuration for the low noise amplifier corresponding to the variable status of the plurality of statuses of the device by, in response to a determination that the device is in the fourth status, operating the variable low noise amplifier with a fourth linearity configuration for the variable low noise amplifier.

In some aspects, the techniques described herein relate to a device wherein the radio frequency front-end is configured to vary the linearity configuration for the low noise amplifier corresponding to the variable status of the plurality of statuses of the device by, testing the status of the device in a time interval to check whether the linearity configuration for the low noise amplifier shall be varied according to the status of the device.

In some aspects, the techniques described herein relate to a device wherein the device is one of a mobile phone, a tablet, a laptop, an IoT device, or a wireless-connected vehicle.

In some aspects, the techniques described herein relate to a method, including: varying a linearity configuration for a variable low noise amplifier of a radio frequency front-end of a device corresponding to a variable status of a plurality of statuses of the device.

In some aspects, the techniques described herein relate to a method wherein varying the linearity configuration for the low noise amplifier corresponding to the variable status of the plurality of statuses of the device includes: determining whether the device is in a first status or in a second status of a plurality of statuses for the device.

In some aspects, the techniques described herein relate to a method wherein varying the linearity configuration for the low noise amplifier corresponding to the variable status of the plurality of statuses of the device includes: in response to a determination that the device is in the first status, operating the variable low noise amplifier with a first linearity configuration for the variable low noise amplifier according to the first status of the device.

In some aspects, the techniques described herein relate to a method wherein varying the linearity configuration for the low noise amplifier corresponding to the variable status of the plurality of statuses of the device includes: in response to a determination that the device is in the second status, operating the variable low noise amplifier with a second linearity configuration for the variable low noise amplifier according to the second status of the device.

In some aspects, the techniques described herein relate to a method wherein varying the linearity configuration for the low noise amplifier corresponding to the variable status of the plurality of statuses of the device includes: in response to a determination that the device is in the second status, determining whether the device is in a third status or in a fourth status of the plurality of statuses for the device.

In some aspects, the techniques described herein relate to a method wherein the third status corresponds to a situation in which no jammer is present.

In some aspects, the techniques described herein relate to a method wherein varying the linearity configuration for the low noise amplifier corresponding to the variable status of the plurality of statuses of the device includes: in response to a determination that the device is in the third status, operating the variable low noise amplifier with a third linearity configuration for the variable low noise amplifier.

In some aspects, the techniques described herein relate to a method wherein the second linearity configuration for the variable low noise amplifier and the third linearity configuration for the variable low noise amplifier are the same linearity configurations.

In some aspects, the techniques described herein relate to a method wherein the second linearity configuration for the variable low noise amplifier and the third linearity configuration for the variable low noise amplifier are the same linearity configurations.

In some aspects, the techniques described herein relate to a method wherein varying the linearity configuration for the low noise amplifier corresponding to the variable status of the plurality of statuses of the device includes: in response to a determination that the device is in the fourth status, operating the variable low noise amplifier with a fourth linearity configuration for the variable low noise amplifier.

In some aspects, the techniques described herein relate to a method wherein varying the linearity configuration for the low noise amplifier corresponding to the variable status of the plurality of statuses of the device includes: testing the status of the device in a time interval to check whether the linearity configuration for the low noise amplifier shall be varied according to the status of the device.

In some aspects, the techniques described herein relate to a method wherein the device is one of a mobile phone, a tablet, a laptop, an IoT device, or a wireless-connected vehicle.

In some aspects, the techniques described herein relate to a variable low noise amplifier configured to amplify a radio frequency input signal to generate an radio frequency output signal according to a linearity configuration of a plurality of linearity configurations for the variable low noise amplifier, the variable low noise amplifier including a plurality of inputs, the plurality of inputs including: a first input configured to receive the radio frequency input signal; and a second input configured to receive a signal corresponding to a variable status of a plurality of statuses of a device.

In some aspects, the techniques described herein relate to a variable low noise amplifier wherein the plurality of inputs further includes a third input configured to receive a signal indicating a jammer affecting the radio frequency input signal, the third input defining the variable status of the device.

In some aspects, the techniques described herein relate to a variable low noise amplifier wherein the variable low noise amplifier is configured to operate in the linearity configuration for the variable low noise amplifier according to the variable status of a device.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4A is a schematic diagram of one example of a communication system that operates with beamforming.

FIG. 4B is a schematic diagram of one example of beamforming to provide a transmit beam.

FIG. 4C is a schematic diagram of one example of beamforming to provide a receive beam.

FIG. 5A is a schematic diagram of one embodiment of a low noise amplifier (LNA).

FIG. 5B is a schematic diagram of another embodiment of an LNA.

FIG. 5C is a schematic diagram of one embodiment of a biasing circuit for an LNA.

FIG. 6A is a schematic diagram of one embodiment of an LNA current bias circuit.

FIG. 6B is a schematic diagram of one embodiment of a servo amplifier for an LNA current bias circuit.

FIG. 6C is a schematic diagram of another embodiment of a servo amplifier for an LNA current bias circuit.

FIG. 7 is a schematic diagram of one embodiment of a controllable reference current source.

FIG. 8 is a schematic diagram of one embodiment of an output match circuit for an LNA.

FIG. 9 is a schematic diagram of one embodiment of a variable LNA.

FIG. 10 is a schematic diagram of one embodiment of a circuit for IIP3 variation of a variable LNA.

FIG. 11 a schematic diagram of one embodiment of a circuit for IIP3 variation of a variable LNA.

FIG. 12 is a schematic diagram of one embodiment of a mobile device.

FIG. 13A is a schematic diagram of one embodiment of a packaged module.

FIG. 13B is a schematic diagram of a cross-section of the packaged module of FIG. 13A taken along the lines 13B-13B.

FIG. 14 is a flowchart depicting a method of varying IIP3 in a variable amplifier according to certain embodiments.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

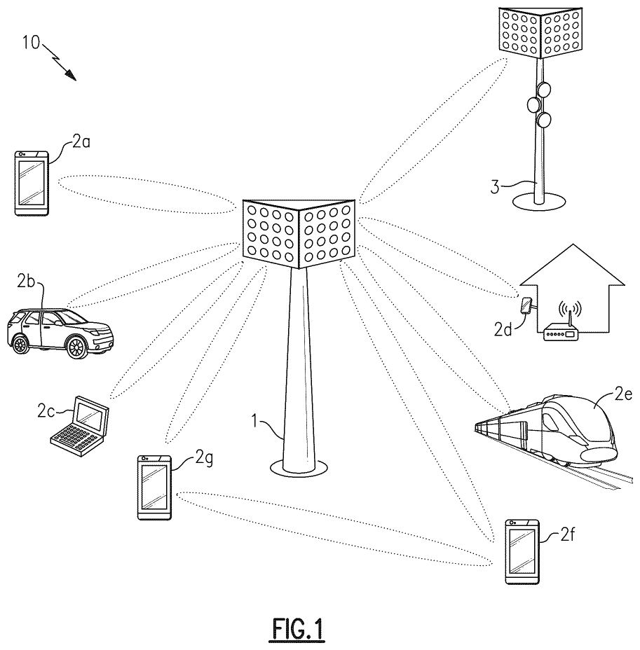

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contfig. rast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mM TC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

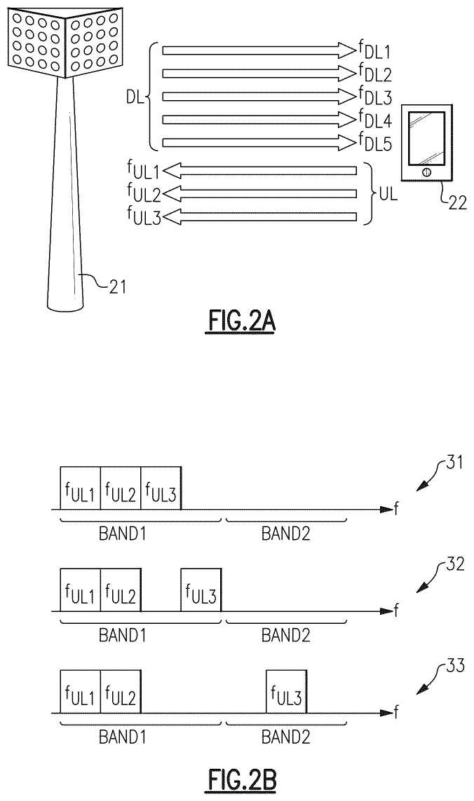

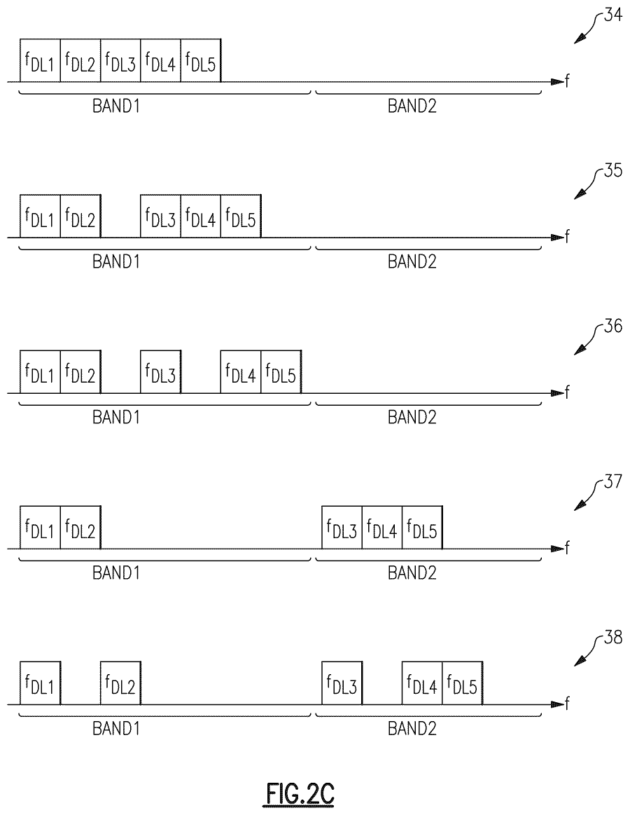

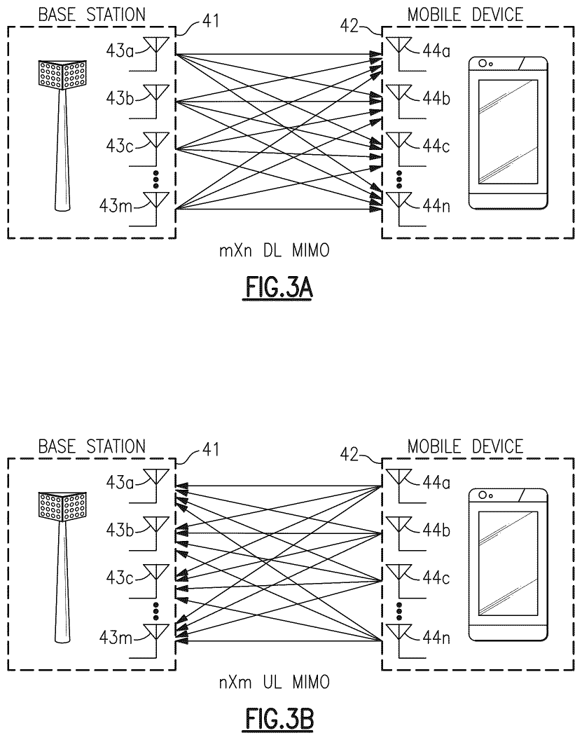

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

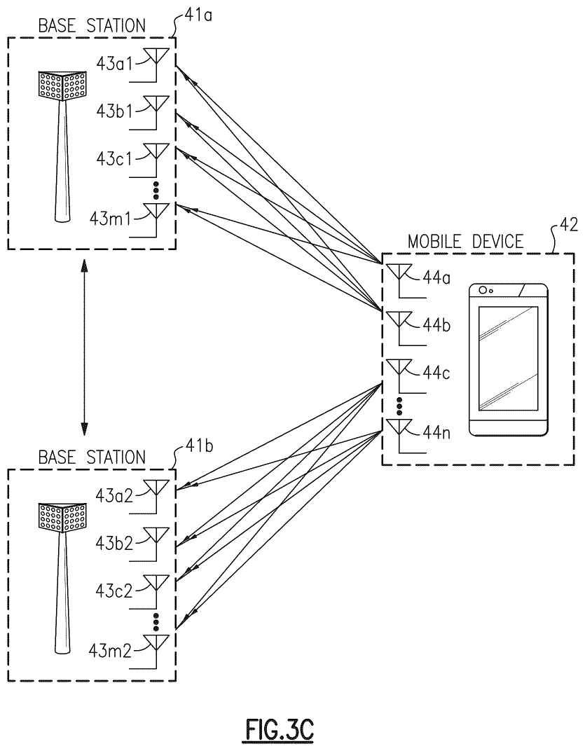

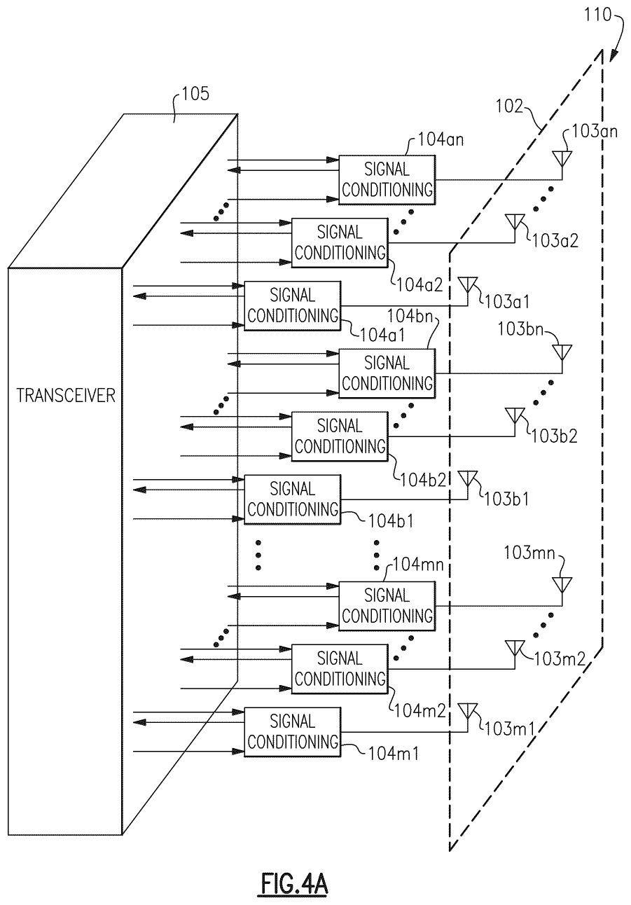

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

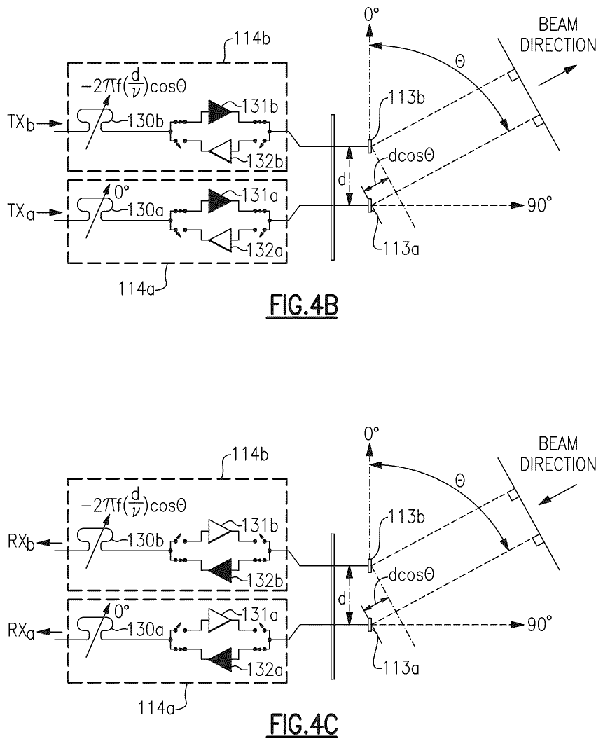

FIG. 4A is a schematic diagram of one example of a communication system 110 that operates with beamforming. The communication system 110 includes a transceiver 105, signal conditioning circuits 104a1, 104a2 . . . 104an, 104b1, 104b2 . . . 104bn, 104m1, 104m2 . . . 104mn, and an antenna array 102 that includes antenna elements 103a1, 103a2 . . . 103an, 103b1, 103b2 . . . 103bn, 103m1, 103m2 . . . 103mn.

Communications systems that communicate using millimeter wave carriers (for instance, 30 GHz to 300 GHz), centimeter wave carriers (for instance, 3 GHz to 30 GHz), and/or other frequency carriers can employ an antenna array to provide beam formation and directivity for transmission and/or reception of signals.

For example, in the illustrated embodiment, the communication system 110 includes an array 102 of m×n antenna elements, which are each controlled by a separate signal conditioning circuit, in this embodiment. As indicated by the ellipses, the communication system 110 can be implemented with any suitable number of antenna elements and signal conditioning circuits.

With respect to signal transmission, the signal conditioning circuits can provide transmit signals to the antenna array 102 such that signals radiated from the antenna elements combine using constructive and destructive interference to generate an aggregate transmit signal exhibiting beam-like qualities with more signal strength propagating in a given direction away from the antenna array 102.

In the context of signal reception, the signal conditioning circuits process the received signals (for instance, by separately controlling received signal phases) such that more signal energy is received when the signal is arriving at the antenna array 102 from a particular direction. Accordingly, the communication system 110 also provides directivity for reception of signals.

The relative concentration of signal energy into a transmit beam or a receive beam can be enhanced by increasing the size of the array. For example, with more signal energy focused into a transmit beam, the signal is able to propagate for a longer range while providing sufficient signal level for RF communications. For instance, a signal with a large proportion of signal energy focused into the transmit beam can exhibit high effective isotropic radiated power (EIRP).

In the illustrated embodiment, the transceiver 105 provides transmit signals to the signal conditioning circuits and processes signals received from the signal conditioning circuits. As shown in FIG. 4A, the transceiver 105 generates control signals for the signal conditioning circuits. The control signals can be used for a variety of functions, such as controlling the gain and phase of transmitted and/or received signals to control beamforming.

FIG. 4B is a schematic diagram of one example of beamforming to provide a transmit beam. FIG. 4B illustrates a portion of a communication system including a first signal conditioning circuit 114a, a second signal conditioning circuit 114b, a first antenna element 113a, and a second antenna element 113b.

Although illustrated as included two antenna elements and two signal conditioning circuits, a communication system can include additional antenna elements and/or signal conditioning circuits. For example, FIG. 4B illustrates one embodiment of a portion of the communication system 110 of FIG. 4A.

The first signal conditioning circuit 114a includes a first phase shifter 130a, a first power amplifier 131a, a first low noise amplifier (LNA) 132a, and switches for controlling selection of the power amplifier 131a or LNA 132a. Additionally, the second signal conditioning circuit 114b includes a second phase shifter 130b, a second power amplifier 131b, a second LNA 132b, and switches for controlling selection of the power amplifier 131b or LNA 132b.

Although one embodiment of signal conditioning circuits is shown, other implementations of signal conditioning circuits are possible. For instance, in one example, a signal conditioning circuit includes one or more band filters, duplexers, and/or other components.

In the illustrated embodiment, the first antenna element 113a and the second antenna element 113b are separated by a distance d. Additionally, FIG. 4B has been annotated with an angle Θ, which in this example has a value of about 90° when the transmit beam direction is substantially perpendicular to a plane of the antenna array and a value of about 0° when the transmit beam direction is substantially parallel to the plane of the antenna array.

By controlling the relative phase of the transmit signals provided to the antenna elements 113a, 113b, a desired transmit beam angle Θ can be achieved. For example, when the first phase shifter 130a has a reference value of 0°, the second phase shifter 130b can be controlled to provide a phase shift of about −2πf(d/v)cos Θ radians, where f is the fundamental frequency of the transmit signal, d is the distance between the antenna elements, v is the velocity of the radiated wave, and π is the mathematic constant pi.

In certain implementations, the distance d is implemented to be about ½λ, where λ is the wavelength of the fundamental component of the transmit signal. In such implementations, the second phase shifter 130b can be controlled to provide a phase shift of about −π cos Θ radians to achieve a transmit beam angle Θ.

Accordingly, the relative phase of the phase shifters 130a, 130b can be controlled to provide transmit beamforming. In certain implementations, a baseband processor and/or a transceiver (for example, the transceiver 105 of FIG. 4A) controls phase values of one or more phase shifters and gain values of one or more controllable amplifiers to control beamforming.

FIG. 4C is a schematic diagram of one example of beamforming to provide a receive beam. FIG. 4C is similar to FIG. 4B, except that FIG. 4C illustrates beamforming in the context of a receive beam rather than a transmit beam.

As shown in FIG. 4C, a relative phase difference between the first phase shifter 130a and the second phase shifter 130b can be selected to about equal to −2πf(d/v)cos Θ radians to achieve a desired receive beam angle Θ. In implementations in which the distance d corresponds to about ½λ, the phase difference can be selected to about equal to −π cos Θ radians to achieve a receive beam angle Θ.

Although various equations for phase values to provide beamforming have been provided, other phase selection values are possible, such as phase values selected based on implementation of an antenna array, implementation of signal conditioning circuits, and/or a radio environment.

### Examples of LNAs and LNA Biasing

Apparatus and methods for biasing of LNAs are provided herein. In certain embodiments, an LNA includes at least one transistor that amplifies a radio frequency (RF) input signal, and a bias circuit including a current bias circuit that generates a bias current based on a reference current and a voltage bias circuit that generates at least one input bias voltage for the at least one transistor based on the bias current. The current bias circuit includes a first bias transistor that receives the reference current, a second bias transistor that generates the bias current, and an amplifier that controls a first bias voltage of the first bias transistor to match a second bias voltage of the second bias transistor.

By implementing the LNA biasing in this manner, fast biasing, accurate matching of the bias current to the reference current, smaller circuit area, and/or superior voltage headroom is achieved.

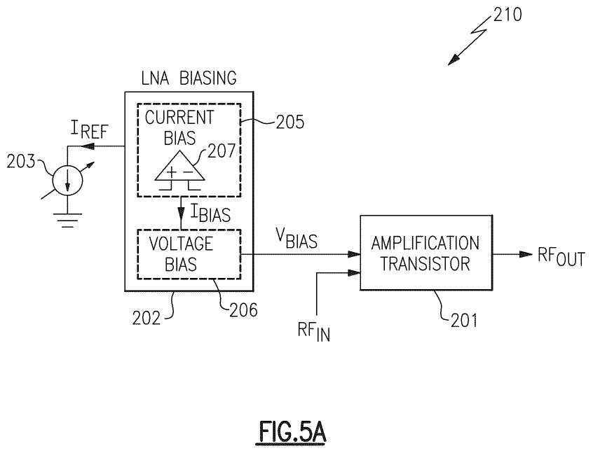

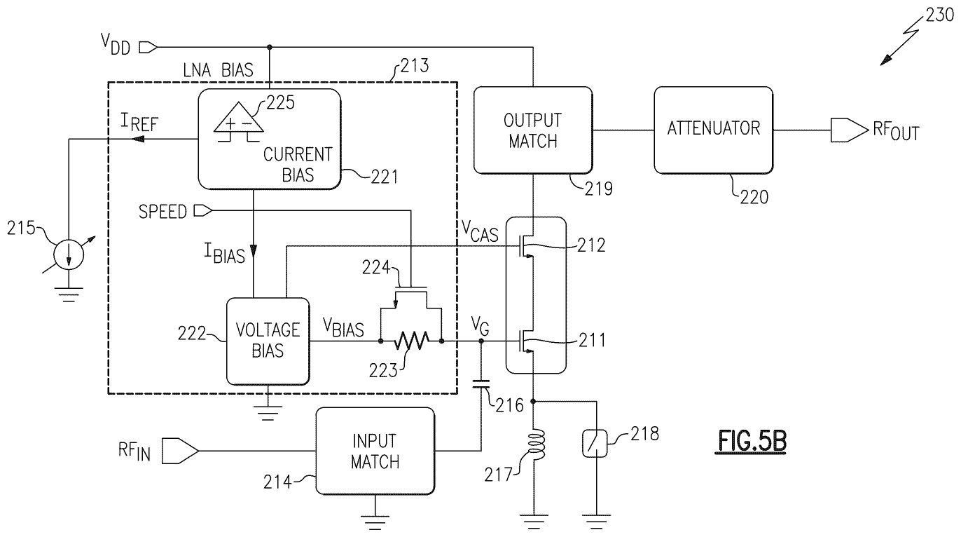

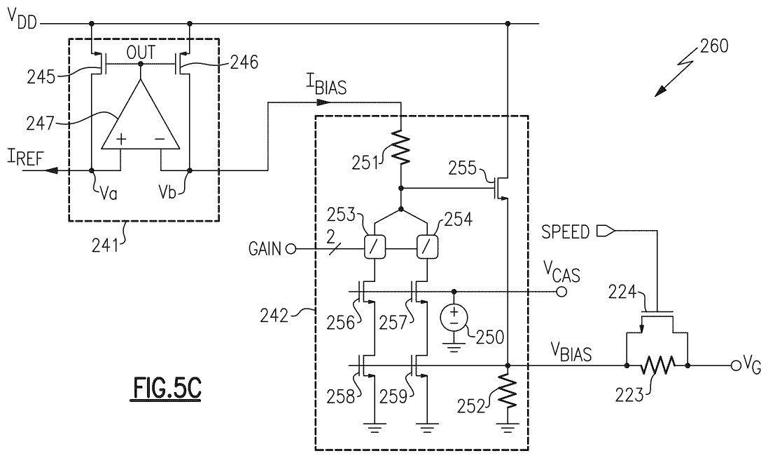

FIG. 5A is a schematic diagram of one embodiment of an LNA 210. The LNA 210 includes an amplification transistor 201, a biasing circuit 202, and a reference current source 203.

As shown in FIG. 5A, the amplification transistor 201 amplifies an RF input signal RF_{IN} to generate an RF output signal RF_{OUT}. Additionally, the amplification transistor 201 is biased by a bias voltage V_{BIAS} generated by the biasing circuit 202. Although shown as including one amplification transistor 201, the LNA 210 can include one or more additional transistors that amplify the RF input signal RF_{IN}. For instance, in one example the LNA 210 is implemented as a cascode amplifier including a common-source transistor biased by a first bias voltage and a cascode transistor biased by a second bias voltage.

The reference current source 203 generates a reference current I_{REF} that is provided to the biasing circuit 202. The reference current source 203 is controllable in this example. For instance, in one example the reference current I_{REF} is digitally controllable to provide gain control (to adjust the amount of amplification the LNA provided to the RF input signal RF_{IN}) and/or trimming to account for variation, such as process, voltage, and/or temperature (PVT) variation.

With continuing reference to FIG. 5A, the biasing circuit 202 includes a current bias circuit 205 and a voltage bias circuit 206. The current bias circuit 205 generates a bias current I_{BIAS} based on the reference current I_{REF}, while the voltage bias circuit 206 generates the bias voltage V_{BIAS} based on the bias current I_{BIAS}.

In certain implementations, the current bias circuit 205 includes a first bias transistor that receives the reference current I_{REF}, a second bias transistor that generates the bias current I_{BIAS}, and an amplifier 207 that controls a first bias voltage of the first bias transistor to match a second bias voltage of the second bias transistor. By implementing the current bias circuit 205 in this manner, accurate matching of the bias current I_{BIAS} to the reference current I_{REF} is achieved. Moreover, such accurate matching can be achieved without the use of cascode transistors in the current bias circuit, thereby achieving smaller area and/or superior voltage headroom that permits the LNA 210 to operate at low supply voltage levels.

Furthermore, including the amplifier 207 allows the bias current I_{BIAS} to quickly reach a steady-state level after enabling the LNA 210, thereby providing the LNA 210 with fast biasing. Such speed in providing proper bias allows the LNA 210 to be quickly turned on or off, which is particularly advantageous in 5G applications associated with short time windows for transitioning between a transmit frame and a receive frame for 5G NR TDD bands.

FIG. 5B is a schematic diagram of another embodiment of an LNA 230. The LNA 230 includes a common-source field-effect transistor (FET) 211, a cascode FET 212, a biasing circuit 213, an input match circuit 214, a reference current source 215, a DC blocking capacitor 216, a degeneration inductor 217, a degeneration bypass switch 218, an output match circuit 219, and an attenuator 220. The LNA 230 receives a power supply voltage V_{DD} and a ground voltage (ground), and serves to amplify an RF input signal RF_{IN} to generate an RF output signal RF_{OUT}.

As shown in FIG. 5B, the common source FET 211 includes a gate that receives RF input signal RF_{IN} by way of the input match circuit 214 and the DC blocking capacitor 216. The gate voltage V_{G} of the common source FET 211 is also biased by a gate bias voltage V_{BIAS} from the biasing circuit 213. The degeneration inductor 217 and the degeneration bypass switch 218 are connected in parallel between a source of the common source FET 211 and ground, and serve to provide a controllable amount of source degeneration (inductive degeneration) to the common source FET 211. The cascode FET 212 is connected between the output match circuit 219 and a drain of the common source FET 211, and includes a gate biased by as cascode bias voltage V_{CAS} generated by the biasing circuit 213.

With continuing reference to FIG. 5B, the attenuator 220 provides a controllable amount of attenuation to an RF signal provided by the output match circuit 219 to generate the RF output signal RF_{OUT} of the LNA 230. In certain implementations, the attenuator 220 is implemented as a digital-step attenuator (DSA) that provides one mechanism for gain control. Although the attenuator 220 can provide some degree of gain control, other components of the LNA 230 (for instance, the reference current source 215 and/or the biasing circuit 213) also provide gain control. Thus, multiple mechanisms can be provided for controlling the amount of amplification provided by the LNA 230.

The reference current source 215 generates the reference current I_{REF}, which is provided to the biasing circuit 213, in this embodiment. The reference current source 215 is controllable, in this example.

In the illustrated embodiment, the biasing circuit 213 includes a current bias circuit 221, a voltage bias circuit 222, a bias resistor 223, and a resistor bypass switch 224. The current bias circuit 221 generates a bias current I_{BIAS} based on the reference current I_{REF}. In some implementations, the current bias circuit 221 includes a first bias transistor that receives the reference current I_{REF}, a second bias transistor that generates the bias current I_{BIAS}, and an amplifier 225 that controls a first bias voltage of the first bias transistor to match a second bias voltage of the second bias transistor.

With continuing reference to FIG. 5B, the voltage bias circuit 222 generates a gate bias voltage V_{BIAS} and a cascode bias voltage V_{CAS} with at least the gate bias voltage V_{BIAS} being based on the bias current I_{BIAS}. The cascode bias voltage V_{CAS} is provided to the gate of the cascode FET 212. Additionally, the gate bias voltage V_{BIAS} is provided to the gate of the common source FET 211 by way of the parallel combination of the bias resistor 223 and the resistor bypass switch 224. In some implementations, both the gate bias voltage V_{BIAS} and the cascode bias voltage V_{CAS} have voltage levels that change based on the current level of the bias current I_{BIAS}.

As shown in FIG. 5B, the resistor bypass switch 224 is controlled by a speed control signal (SPEED), which can be selectively activated to reduce the amount of resistance between the voltage bias circuit 222 and the gate of the common-source FET 211. Accordingly, a resistor-capacitor (RC) time constant associated with charging or discharging the gate of the common source FET 211 can be selectively reduced by activating the speed control signal. By implementing the LNA biasing in this manner, the benefits of fast gate bias control and high biasing isolation are achieved.

FIG. 5C is a schematic diagram of one embodiment of a biasing circuit 260 for an LNA, such as the LNA 230 of FIG. 5B. The biasing circuit 260 receives a power supply voltage V_{DD}, a ground voltage, a speed control signal (SPEED), a gain control signal (GAIN), and a reference current I_{REF}. The biasing circuit 260 generates a gate bias voltage V_{BIAS}, which is used to control a gate voltage V_{G} of a common source FET. The biasing circuit 260 also generates a cascode bias voltage V_{CAS} used to bias a cascode FET.

In the illustrated embodiment, the biasing circuit 260 includes a current bias circuit 241, a voltage bias circuit 242, a bias resistor 223, and a resistor bypass switch 224. The current bias circuit 241 receives the reference current I_{REF} and generates the bias current I_{BIAS}. The current bias circuit 241 includes a first bias FET 245 that receives the reference current I_{REF}, a second bias FET 246 that generates the bias current I_{BIAS}, and a servo amplifier 247 that controls a first bias voltage Va of the first bias FET 245 to match a second bias voltage Vb of the second bias FET 246. In this embodiment, a first input (+) of the servo amplifier 247 receives the first bias voltage Va, a second input (−) of the servo amplifier 247 receives the second bias voltage Vb, and an output of the servo amplifier 247 controls the gates of the first bias FET 245 and the second bias FET 246 to provide feedback that matches of the drain-to-source voltages of the first bias FET 245 and the second bias FET 246 to one another.

By including the servo amplifier 247, accurate matching of the bias current I_{BIAS} to the reference current I_{REF} is achieved. Moreover, the current bias circuit 241 has excellent voltage headroom that allows the power supply voltage V_{DD} to operate at a low voltage level. Furthermore, the servo amplifier 247 quickly sets the gate voltages of the first bias FET 245 and the second bias FET 246 to a proper biasing level, and thus provides fast biasing that allows an LNA to be quickly turned on or off, which is desirable for TDD applications with a short time windows for transitioning between a transmit frame and a receive frame.

With continuing reference to FIG. 5C, the current bias circuit 242 includes a voltage source 250, a first biasing resistor 251, a second biasing resistor 252, a first gain control switch 253, a second gain control switch 254, a first biasing FET 255, a second biasing FET 256, a third biasing FET 257, a fourth biasing FET 258, and a fifth biasing FET 259. The bias current I_{BIAS} flows through the first biasing resistor 251 to control a gate voltage of the first biasing FET 255, which provides a current that flows through the second biasing resistor 252 to set the bias voltage V_{BIAS}. The bias current I_{BIAS} also flows through the series combination of the second biasing FET 256 and the fourth biasing FET 258 and/or the series combination of the third biasing FET 257 and the fifth biasing FET 259 based on the setting of the first gain control switch 253 and the second gain control switch 254 (controlled by the gain control signal GAIN).

Although not depicted in FIG. 5C, a wide variety of biasing schemes (for instance, feedback schemes) can be used to control a voltage level of the voltage source 250 to set the gate voltage of the second biasing FET 256 and the third biasing FET 257 (and thus the cascode bias voltage V_{CAS}) based on the amount of current flowing therethrough (corresponding to I_{BIAS}).

The gate bias voltage V_{BIAS} is used to control the gate voltage V_{G} through the parallel combination of the bias resistor 223 and the resistor bypass switch 224. The resistor bypass switch 224 is controlled by the speed control signal (SPEED).

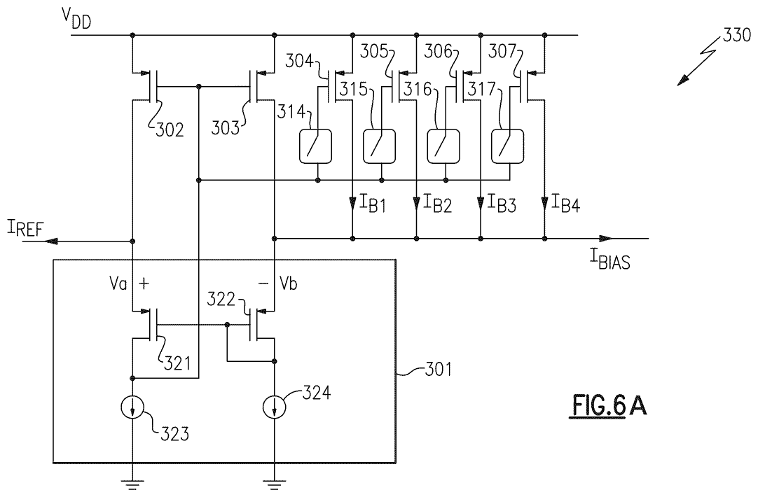

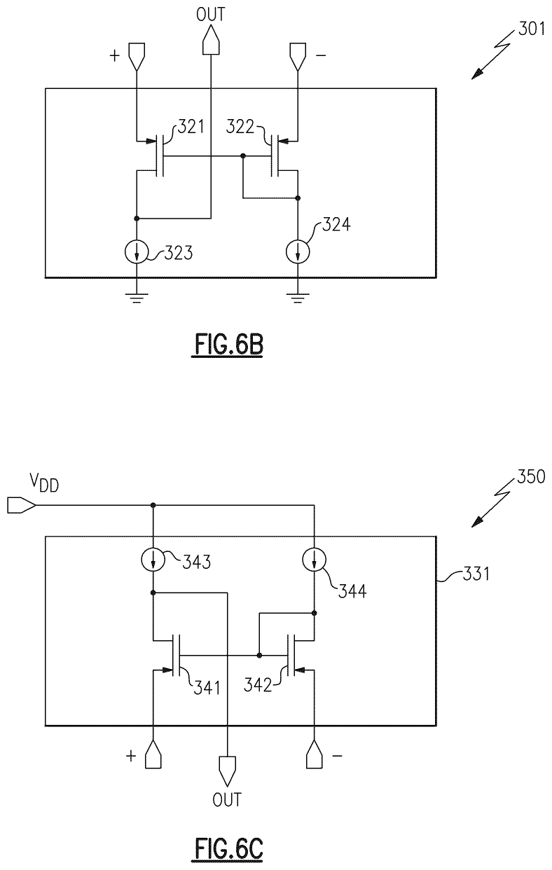

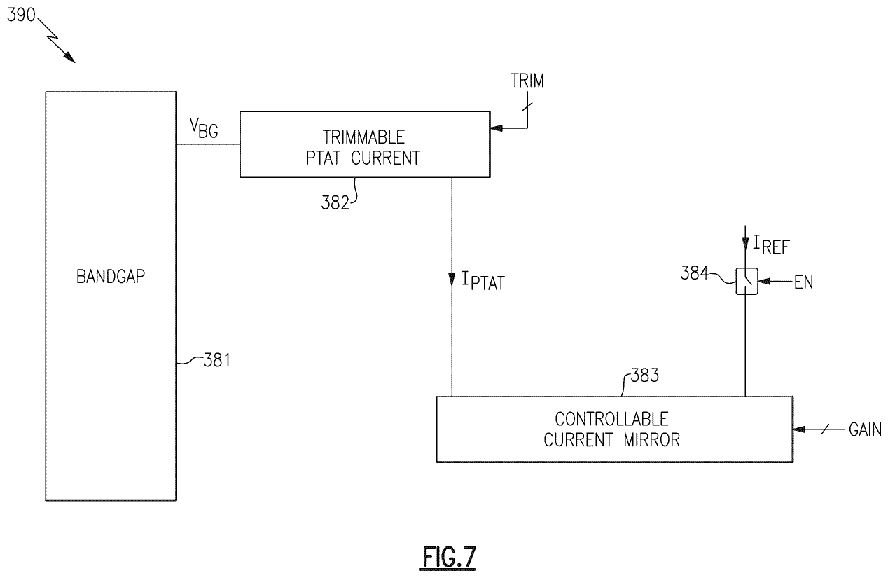

FIG. 6A is a schematic diagram of one embodiment of an LNA current bias circuit 330. The current bias circuit 330 includes a servo amplifier 301, a first biasing FET 302, a second biasing FET 303, a first selectable mirroring FET 304, a second selectable mirroring FET 305, a third selectable mirroring FET 306, a fourth selectable mirroring FET 307, a first selection switch 314, a second selection switch 315, a third selection switch 316, and a fourth selection switch 317.

As shown in FIG. 6A, the first bias FET 302 receives the reference current I_{REF}, the second bias FET 303 generates the bias current I_{BIAS}, and the servo amplifier 301 controls a first bias voltage Va of the first bias FET 302 to match a second bias voltage Vb of the second bias FET 303. Additionally, a first input (+) of the servo amplifier 301 receives the first bias voltage Va, a second input (−) of the servo amplifier 301 receives the second bias voltage Vb, and an output of the servo amplifier 301 controls the gates of the first bias FET 302 and the second bias FET 303 to provide feedback that matches the drain-to-source voltage of the first bias FET 302 to the drain-to-source voltage of the second bias FET 303.

The selectable mirroring FETs 304-307 can be selectively activated by the selection switches 314-317, respectively, to increase the bias current I_{BIAS} to provide gain control. Thus, currents 181, 182, 183, and/or 184 generated by the mirroring FETs 304-307, respectively, can be selectively added to the current generated by the second bias FET 303. When activated, the selectable mirroring FETs 304-307 operate with the same gate-to-source and source-to-drain voltages as the second bias FET 303 due to the feedback provided by the servo amplifier 301.

In the illustrated embodiment, the servo amplifier 301 includes a first amplifier FET 321, a second amplifier FET 322, a first current source 323, and a second current source 324. However, other implementations are possible.

FIG. 6B is a schematic diagram of one embodiment of a servo amplifier 301 for an LNA current bias circuit. The servo amplifier 301 includes a first amplifier FET 321, a second amplifier FET 322, a first current source 323, and a second current source 324. The first amplifier FET 321 and the second amplifier FET 322 are p-type, in this example.

FIG. 6C is a schematic diagram of another embodiment of a servo amplifier 350 for an LNA current bias circuit. The servo amplifier 350 includes a first amplifier FET 341, a second amplifier FET 342, a first current source 343, and a second current source 344. The first amplifier FET 341 and the second amplifier FET 342 are n-type, in this example. The servo amplifier 350 of FIG. 6C corresponds to a complementary implementation of the servo amplifier 301 of FIG. 6B in which a transistor polarity is reversed.

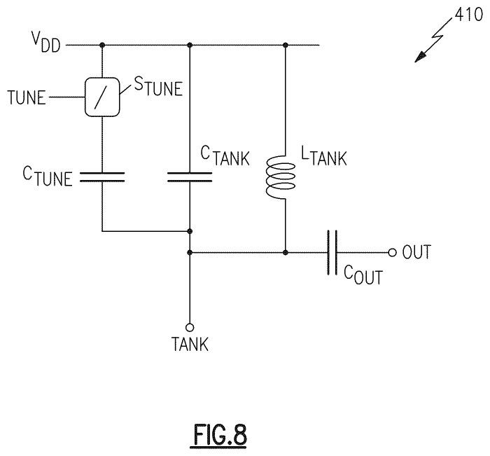

FIG. 7 is a schematic diagram of one embodiment of a controllable reference current source 390. The controllable reference current source 390 includes a bandgap circuit 381, a trimmable proportional to absolute temperature (PTAT) current source 382, a controllable current mirror 383, and an enable switch 384.

The bandgap circuit 381 generates a bandgap voltage V_{BG} used to bias the trimmable PTAT current source 382. The trimmable PTAT current source 382 generates a PTAT current I_{PTAT}, which is trimmable by a trimming control signal TRIM (a multi-bit digital signal, in this example) to provide enhanced accuracy. The controllable current mirror 383 mirrors the PTAT current I_{PTAT} to generate a reference current I_{REF} that is provided at an output when the enable switch 384 is activated by an enable signal EN. The controllable current mirror 383 has a controllable gain set by a gain control signal GAIN (a multi-bit digital signal, in this example).

FIG. 8 is a schematic diagram of one embodiment of an output match circuit 410 for an LNA. The output match circuit 410 includes a tank capacitor C_{TANK}, a tank inductor L_{TANK}, a tuning capacitor C_{TUNE}, a tuning switch S_{TUNE}, and an output capacitor C_{OUT}. The output match circuit 410 includes a tank node TANK for connecting to one or more amplification transistors of an LNA, and an output node OUT for providing an output signal.

As shown in FIG. 8, the tank capacitor C_{TANK} and the tank inductor L_{TANK} are connected in parallel between the output node OUT and a supply voltage V_{DD}. Additionally, when the tuning switch S_{TUNE} is activated (closed), the tuning capacitor C_{TUNE} IS in parallel with the tank capacitor C_{TANK} to adjust the amount of tank capacitance. The output capacitor C_{OUT} is connected between the tank node TANK and the output node OUT.

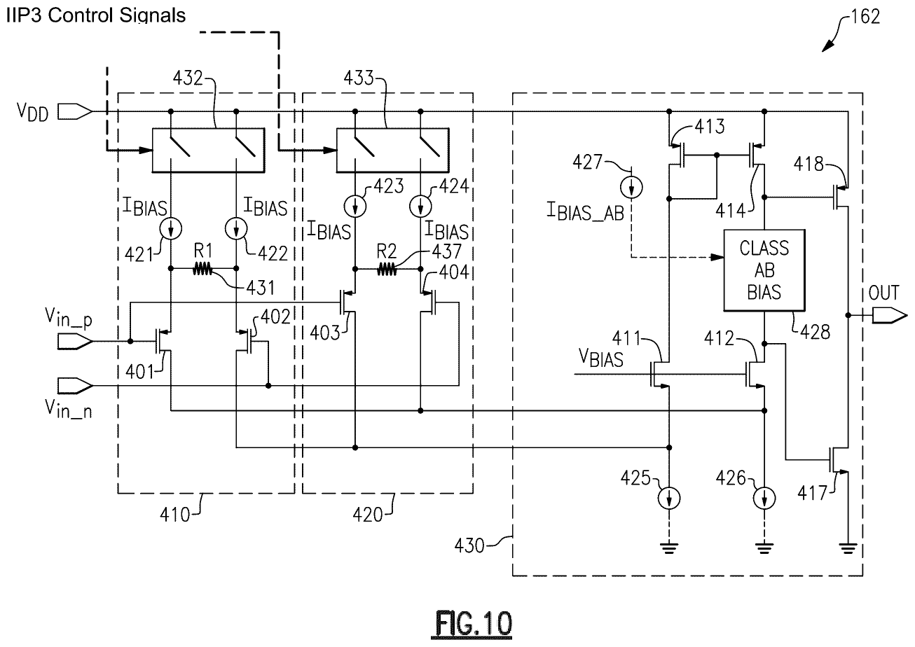

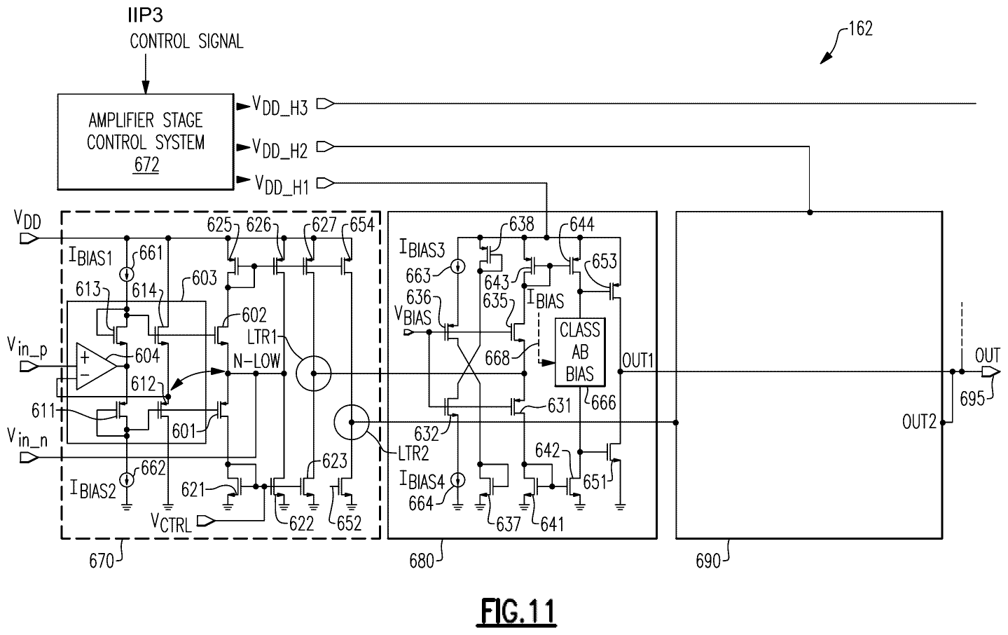

Circuits shown in anyone of FIGS. 5A, 5B, 5C, 6, 7, and 8 may be combined with the circuits for IIP3 variation shown in FIG. 10 and/or FIG. 11 to provide the functionality described above.

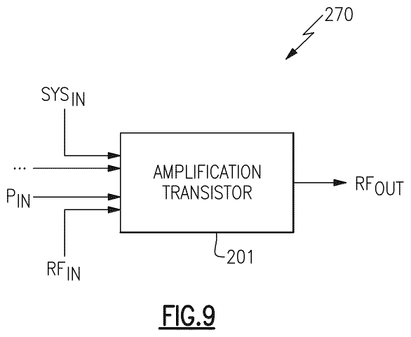

FIG. 9 is a schematic diagram of one embodiment of a variable LNA 270. The variable LNA 270 comprises an amplification transistor 201 with a plurality of inputs. As shown in FIG. 9, the variable amplification transistor 201 amplifies an RF input signal RF_{IN} to generate an RF output signal RF OUT.

Additionally, the amplification transistor 201 may be biased based on an input power P_{IN} which may be measured at the receive path providing the RF input signal RF_{IN}. The input power P_{IN} may be indicative of a jammer that affects the RF communication of the RF communication system having the LNA 270. The input power P_{IN} in some embodiments may be an average power measurement.

Additionally or alternatively, the amplification transistor 201 may be biased based on a status of a system SYS_{IN}. The status of a system SYS_{IN} may be indicative of a status of the device having the RF communication system with the LNA 270. The status may, for example, be a parking status, a storage status, or a status derived from the environment in which the device is being used, such as an environment with increased likelihood of the presence of a jammer or an environment with a reduced likelihood of the presence of a jammer.

The status of a system SYS_{IN} may be derived directly and/or derived using machine learning from a plurality of input parameters including at least some of the plurality of inputs of the the variable LNA 270. In vehicular applications, input parameters may for instance be derived from information received using the Cellular Vehicle-to-Everything (CV2X) technology and/or using the Global Navigation Satellite System GNSS technology providing for instance a relative position and/or a geographical location.

Although shown as including one amplification transistor 201, the variable LNA 270 can include one or more additional transistors that amplify the RF input signal RF_{IN}. For instance, in one example variable LNA 270 is implemented as a cascode amplifier including a common-source transistor biased by a first bias voltage and a cascode transistor biased by a second bias voltage.

FIG. 10 is a schematic diagram of an embodiment of a variable amplifier 162 (e.g., an LNA 162) configured for IIP3 variation. The amplifier 162 may include the variable LNA 270 shown in FIG. 9. The circuit 340 is configured to vary IIP3 by varying I_{DD}. As shown, I_{DD} may be varied using a plurality of switches 432, 433 to selectively couple a power supply voltage V_{DD} to a respective transistor. The variable amplifier 162 supports adaptive biasing of an amplification stage based on a status, e.g., a parking status, a storage status, or an on/off status of a vehicle. The variable amplifier 162 is a differential amplification circuit. Although one example of a suitable differential amplification circuit is shown, a variably biased differential amplifier may be implemented in a wide variety of ways. In various implementations, the variable amplifier 162 may include one or more controllable biasing stages that control the IIP3 of the variable amplifier 162 by controlling the bias (e.g., the bias current) provided to the variable amplifier 162 (e.g., to an amplifying stage of the variable amplifier 162). In some cases, the IIP3 control signal may control the one or more controllable biasing stages to adjust the IIP3 of the variable amplifier 162. In some embodiments, the variable amplifier 162 includes a plurality of amplifying stages where one or more amplifying stages may also function as controllable biasing stages. These controllable amplifying/biasing stages, herein referred to as biasing stages, may control the I_{DD} of the one or more amplifying stages (e.g., subsequent amplifying stages), by adjusting the bias (e.g., a bias voltage or bias current) of the one or more amplifying stages.

As shown in FIG. 10, the variable amplification circuit 162 includes a first amplifying/biasing stage or biasing stage 410, a second amplifying/biasing or biasing stage 420 and a third amplifying stage 430. The first biasing stage 410 and the second biasing stage 420 are individually controlled stages that control the I_{DD} of the differential amplification circuit 162 by controlling the bias currents provided to the amplifying stage 430. The first biasing stage 410 is controlled by a first I_{DD} control switch 432 and the second biasing stage 420 is controlled by a second I_{DD} control switch 433.

In some examples, referring to FIG. 9, the RF input signal RF_{IN} may be provided to the first biasing stage 410 and the second biasing stage 420 as a differential input Vin_p, Vin_n.

The first biasing stage 410 includes a first pair of p-type field effect transistors (PFETs) 401-402 for amplifying the differential input Vin_p, Vin_n, for example, corresponding to the RF input signal RF_{IN}. The first pair of PFETs 401-402 is biased by a first pair of current sources 421-422 (each providing a current I_{BIAS} to the corresponding PFET, in this example), and includes a first resistor 431 of resistance R1 for coupling the source of the PFET 401 to the source of the PFET 402. The first pair of current sources 421-422 may be enabled or disabled using the 432 that may be controlled by the IIP3 control signal. The IIP3 control signal can be generated by a processor or control circuit, depending on the embodiment.

The second stage 420 includes a second pair of p-type field effect transistors (PFETs) 403-404 for amplifying the differential input Vin_p, Vin_n. The second pair of PFETs 401-402 is biased by a second pair of current sources 423-424 (each providing a current I_{BIAS} to the corresponding PFET, in this example), and includes a second resistor 437 of resistance R2 for coupling the source of the PFET 403 to the source of the PFET 404. The second pair of current sources 423-424 may be enabled or disabled using the I_{DD} control switch 433 that may be also controlled by the IIP3 control signal described above.

Each of the I_{DD} control switch 432 and the I_{DD} control switch 433 may include a pair of electronically controlled switches used to enable or disable the first pair of current sources 421-422 or the second pair of current sources 423-424 provided to the first pair of PFETs 401-402 and the second pair of PFETs 403-404 respectively. The I_{DD} control switches 432 and 433 may be controlled based at least in part on a status, such as a parking status, a storage status, on/off status, or other status of a vehicle or other device on which the variable amplifier 162 resides.

Current from the first pair of PFETs 401-402 and the second pair of PFETs 403-404 are combined using folded cascade circuitry that includes current sources 425-426, n-type field effect transistors (NFETs) 411-412, and PFETs 413-414. In this example, the gates of NFETs 411-412 are controlled by a bias voltage V_{BIAS}. In some cases, V_{BIAS} is a constant voltage provided by a voltage supply.

The differential amplification circuit 162 further includes a push-pull output stage including NFET 417, PFET 418, a current source 427, and a class AB bias circuit 428. As shown in FIG. 9, the current source 427 provides a current I_{BIAS_AB} to the class AB bias circuit 428, which biases the NFET 417 and PFET 418 to provide enhanced bandwidth.

The differential amplification circuit 162 may be adaptively controlled using the first I_{DD} control switch 432 and the second I_{DD} control switch 433 based on the IIP3 control signal. In such cases, the I_{DD} of the third amplifying stage 430 and therefore that of the variable amplifier 162 may be increased where higher IIP3 is desired, by enabling both the first pair of current sources 421-422 and the second pair of current sources 423-424 using the first I_{DD} control switch 432 and the second I_{DD} control switch 433. Correspondingly, the I_{DD} of the third amplifying stage 430 and therefore that of the variable amplifier 162 may be decreased wherein lower IIP3 and less power consumption is desirable, by disabling one of current sources (421-422 and 423-424) using the I_{DD} control switches 432 and 433. In some cases, the IIP3 control signal turns off the variable amplifier 162 by disabling both I_{DD} control switches 432/433. As such, the IIP3 control signal may control both the I_{DD} and the ON/OFF state of the variable amplifier 162.

In various embodiments, the variable amplifier 162 may comprise 3, 4 or more individually controlled biasing stages. In some cases, each biasing stage may be activated or deactivated by a control circuit using I_{DD} control switches. In some cases, each biasing stage may be continuously controlled by the control circuit to adjust a bias current.

FIG. 11 a schematic diagram of an embodiment of a circuit for IIP3 variation of a variable amplifier 162 (e.g., an LNA). The variable LNA 162 comprises a plurality of stages 670, 680, 690, where n is greater or equal to 2. The variable amplifier 162 may include the variable LNA 270 shown in FIG. 9. Moreover, the variable amplifier 162 of FIG. 10 can be combined with the variable amplifier 162 of FIG. 11. The variable amplifier 162 may comprise a multi-stage differential amplification circuit.

The example shown, is a three-stage variable amplifier comprising amplification stages 670/680/690 connected in series. In some cases, the variable amplifier 162 may include any number of amplifying stages (e.g., 3, 4, 10, 20). In some such cases, the first amplifying stage 670 may be a primary amplifying stage and the other amplifying stages 680, 690 may be controllable amplifying stages (herein referred to as amplifying stages). The bias voltage V_{DD} provided to the primary stage 670 may be constant while the bias voltage provided to the additional amplifying stages 680/690 may be controlled by an amplifier stage control system 672. The amplifier stage control system 672 may control the IIP3 of the variable amplifier 162 by activating or deactivating the amplifying stages 680/690. In some cases, including more amplifying stages of the variable amplifier 162 can increase IIP3. The amplifier stage control system 672 may control the number of active amplifying stages contributing in the amplification process (e.g., by controlling the corresponding supply voltages) using the IIP3 control signal based at least in part on a status, such as a parking status, a storage status, on/off status, or other status of a vehicle or other device on which the variable amplifier 162 resides. For example, where higher IIP3 is desired, the control signal may add one or more amplifying stages and for situations where lower IIP3 is acceptable and lower power consumption is desired, the IIP3 control signal may deactivate one or more amplifying stages (e.g., by turning off the corresponding supply voltages).

In some implementations, the number of active amplifying stages is controlled by switching the supply voltages Vdd_h1, Vdd_h2 and Vdd_h3 provided to each amplifying stage. For example, the amplifier stage control system 672 may activate or deactivate one or more amplifying stages of the variable amplifier 162. As shown, the amplifier control system 672 receives the IIP3 control signal and controls the supply voltages Vdd_h1, Vdd_h2 and Vdd_h3 provided to each amplifying stage.

As shown in FIG. 11, the primary amplifying stage 670 of the differential amplification circuit includes p-type field-effect transistors (PFETs) 601, 611, 612, 625, 626, 627 and 654. And n-type field-effect transistors (NFETs) 602, 613, 614, 621, 622, 623 and 652. The initial amplifying stage 670 includes a first input Vin_p and a second input Vin_n, which are of different input impedance, and which can be connected to a radio frequency input signal RF_{IN}. In particular, the first input Vin_p is connected to the buffer 604, which can include a transistor gate and/or other high input impedance elements. In contrast, the second input Vin_n connects to sources of PFET 601 and NFET 602 and drains of NFET 622 and PFET 626 at a low impedance node NLow. The initial amplifying stage 670 further includes two bias current sources 661 and 662. Additionally, the variable amplifier 162 includes a buffer 604. As shown in FIG. 11, the buffer 604, the PFET 611, the PFET 612, the NFET 613, and the NFET 614 operate as a first input circuit 603. The buffer 604 includes a positive input of high impedance (for instance, a transistor gate), and a negative input of high impedance (for instance, a transistor gate).

The amplifying stage 680 of the variable amplifier 162 includes p-type field-effect transistors (PFETs) 631, 636, 638, 643, 644, and 653 and n-type field-effect transistors (NFETs) 632, 635, 637, 641, 642, and 651. The amplifying stage 680 further includes two bias current sources 663 and 664, and a class AB bias circuit 666 and a class A B current source 668. The amplifying stage 680 receives input signals from the initial amplifying stage 670 via the junction LTR1 in the initial amplification stage 670.

By implementing the second input Vin_n that receives the RFIN with low impedance, the second input Vin_n can source or sink a relatively large current to quickly charge or discharge internal capacitances of the variable amplifier 162 in response to changes in RFIN.

The primary amplifier 670 generates one or more output currents each provided to a subsequent amplifying stages. The amplifying stages that are activated by the amplifier control system 672, work in parallel to increase the drive and therefore increase IIP3. In the example shown, the primary amplifying stage provides a current to the amplifying stage 680 and amplifying stage 690 via a first node LTR1 and a second node LTR2 respectively. When the amplifying stage 680 and the amplifying stage 690 are both activated, their outputs (OUT1 and OUT2) are combined in the output OUT 695 of the EA 162.

The amplification stage 680 generates an output signal (e.g., an output current) at an output OUT1 that is electrically connected to the output OUT 695 of the variable amplifier 162. Additionally, the amplification stage 680 operates with a class AB bias circuit 666 to provide a push-pull output stage for enhanced bandwidth.

The subsequent amplifying stage 690 may be identical to the amplifying stage 680 and, when activated, amplifies an output signal received from the primary amplifying stage 670 via the node LTR2 and generates an output signal (e.g., an output current) at an output OUT2 that is electrically connected to the output OUT 695 of the variable amplifier 162.

In some implementations, the variable amplifier 162 includes three or more amplifying stages that are individually controlled by the amplifier stage control system 672. In these implementations, the primary stage 670 includes more nodes similar to LTR1 and LTR2 that provide the input to the additional amplifying stages. The outputs of all amplifying stages are combined to generate output OUT 695 of the variable amplifier 162.

With continuing reference to FIG. 11, the amplifying stage 670 and the amplifying stage 680 receive a bias voltages Vdd_h1 and Vdd_h2, for example, from the amplifier stage control system 672. By controlling the state of the Vdd_h1 or Vdd_h2 between ON and OFF states, the amplifier stage control system 672 may change the IIP3 of the variable amplifier circuit 162 by including or excluding one or more amplifying stages in the amplification process.

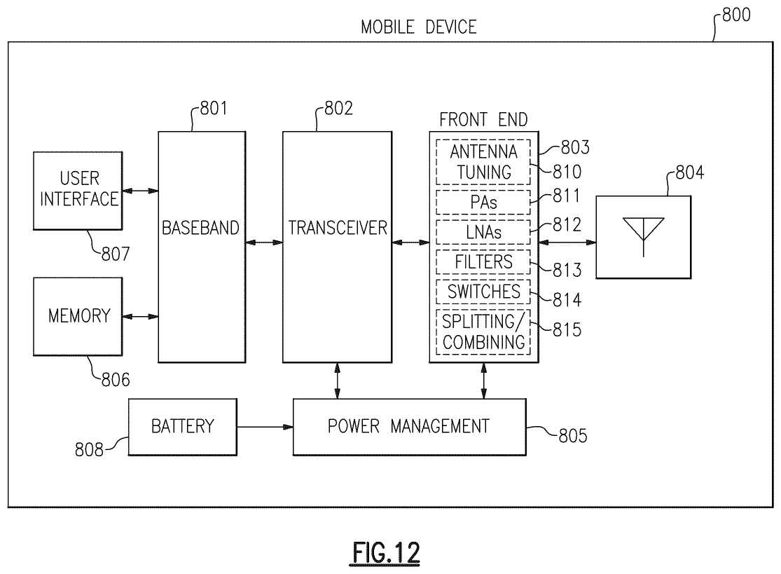

FIG. 12 is a schematic diagram of one embodiment of a mobile device 800. The mobile device 800 includes a baseband system 801, a transceiver 802, a front end system 803, antennas 804, a power management system 805, a memory 806, a user interface 807, and a battery 808. The mobile device 800 may be a vehicle, or maybe included in a vehicle, for example, although the mobile device 800 can be employed in a wide variety of other contexts, such as in a mobile phone, tablet, or laptop, for example.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 12 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAs) 811, low noise amplifiers (LNAs) 812, filters 813, switches 814, and signal splitting/combining circuitry 815. However, other implementations are possible. The LNAs 812 can include one or more LNAs implemented in accordance with the teachings herein.

The front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 12, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 12, the power management system 805 receives a battery voltage from the battery 808. The battery 808 can be any suitable battery for use in the mobile device 800, including, for example, a lithium-ion battery.

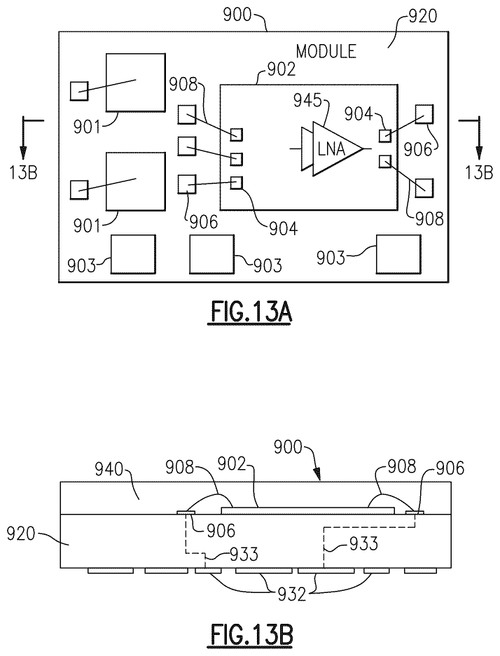

FIG. 13A is a schematic diagram of one embodiment of a packaged module 900. FIG. 13B is a schematic diagram of a cross-section of the packaged module 900 of FIG. 13A taken along the lines 13B-13B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a low noise amplifier 945, which can be implemented in accordance with one or more features disclosed herein.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs).

As shown in FIG. 13B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 13B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

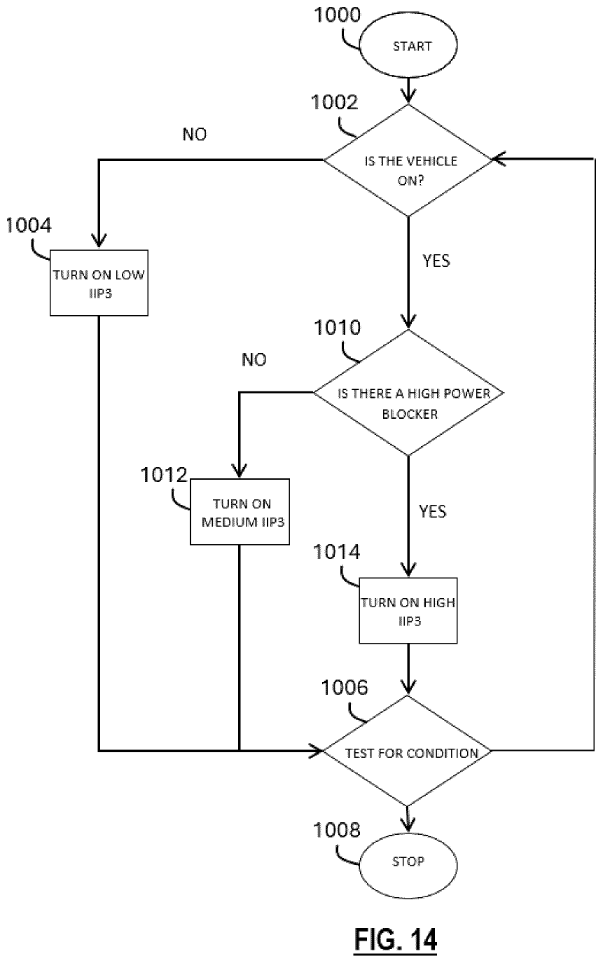

FIG. 14 is a flowchart depicting a method of varying IIP3 in a variable amplifier according to certain embodiments. For example, the method can be used to vary the linearity of any of the variable amplifiers described herein, e.g., with respect to any of FIGS. 5A-11. While the method is described in the context of a vehicle that includes a variable LNA, the method can be employed in other contexts, such as for any type of manned or unmanned vehicle, mobile phone, table, laptop, or other device. The method can be implemented by firmware or software of one or more processors residing on the vehicle, for example.

The illustrated method starts at block 1000 and includes, at block 1002, determining whether the vehicle is on, or otherwise determining whether a reduction in current consumption is appropriate, e.g., while the LNA is unlikely to be in use. For example, the method can include determining, without limitation, a parking status, a storage status, or some status derived from the environment in which the device is being used, such as an environment with increased likelihood of the presence of a jammer or an environment with a reduced likelihood of the presence of a jammer.

If, at block 1002, the method determines that the vehicle is not on, or otherwise determines that a lower IIP3 setting is appropriate, the method moves to block 1004, where the method includes causing the variable LNA to enter a low IIP3 state. As one example, referring to FIG. 11, a processor can generate the IIP3 control signal for controlling the amplifier stage control system 672 of the variable amplifier 162, or the processor can communicate with other control circuitry which in turn generates the IIP3 control signal, depending on the embodiment. Referring still to the variable amplifier 162 of FIG. 11 for illustrative purposes, the method can cause the amplifier stage control system 672 to reduce the number of active amplifier stages, e.g., by outputting V_{DD}_H1 and V_{DD}_H2 so as to deactivate both the second amplifier stage 680 and the third amplifier stage 690.

After causing the variable amplifier to enter the low IIP3 stage, the method moves on to block 1006 and tests for a condition to determine whether the linearity configuration of the variable amplifier should be adjusted or checked for adjustment. For example, the method can include testing the status of the vehicle or other device including the variable LNA. The method can include continuously determining the status or other condition or doing so at some frequency, for instance, once per a given time interval, such as 10 minutes, 30 minutes, 1 hour, 12 hours, a day, or a week. The time interval for testing may be configurable by a user of the device.

If at block 1002 the method determines that the vehicle is on, or otherwise determines that other than a higher IIP3 configuration may be appropriate, the method moves on to block 1010 to determine if a high power blocker has been detected. For example, as discussed previously, an input power P_{IN} may be indicative of a jammer that affects the RF communication of the RF communication system having the variable amplifier. In such a case, if the input power or other measure indicates that no jammer is present, the method moves to block 1012 to set the variable amplifier in a medium IIP3 setting. Returning to FIG. 11 for the purposes of illustration, the processor can output an IIP3 control signal with a value that causes the amplifier stage control system 672 to activate the second amplifying stage 680 but not the third amplifying stage 690, thereby setting the variable amplifier 162 in a configuration with an intermediate IIP3.

If, on the other hand, the method determines that a jammer is present at block 1010, the method can move on to block 1014 to set the variable amplifier 162 in a configuration with a high IIP3. For example, returning again to FIG. 11, the processor can output an IIP3 control signal having a value that causes the amplifier stage control system 672 to activate both of the amplifying stages 680, 690, thereby setting the variable amplifier 162 in a configuration with a high IIP3.

While described with respect to the variable amplifier 162 of FIG. 11, other variable amplifiers can be used in connection with the method of FIG. 14. As one example, the method can include achieving the desired IIP3 configuration by controlling the I_{DD} switches 632, 633 of the variable amplifier of FIG. 10 to increase or decrease the bias current I_{DD} as appropriate, e.g., instead of or in combination with controlling V_{DD} to activate or deactivate additional stages, depending on the embodiment.

### Applications

The principles and advantages of the embodiments herein can be used for any other systems or apparatus that have needs for low noise amplification. Examples of such apparatus include RF communication systems. RF communications systems include, but are not limited to, mobile phones, tablets, base stations, network access points, customer-premises equipment (CPE), laptops, and wearable electronics. Thus, the low noise amplifiers herein can be included in various electronic devices, including, but not limited to, consumer electronic products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A device including a radio frequency front-end, the device comprising:
an antenna; and
a radio frequency front-end including a variable radio frequency amplifier in a linearity configuration of a plurality of linearity configurations for the variable radio frequency amplifier, the radio frequency front-end configured to vary the linearity configuration for the variable radio frequency amplifier corresponding to a variable status of a plurality of statuses of the device.

2. The device of claim 1 wherein the radio frequency front-end is configured to vary the linearity configuration for the variable radio frequency amplifier corresponding to the variable status of the plurality of statuses of the device by determining whether the device is in a first status or in a second status of the plurality of statuses for the device.

3. The device of claim 2 wherein the radio frequency front-end is configured to vary the linearity configuration for the variable radio frequency amplifier corresponding to the variable status of the plurality of statuses of the device by, in response to a determination that the device is in the first status, operating the variable radio frequency amplifier with a first linearity configuration for the variable radio frequency amplifier according to the first status of the device.

4. The device of claim 2 wherein the radio frequency front-end is configured to vary the linearity configuration for the variable radio frequency amplifier corresponding to the variable status of the plurality of statuses of the device by, in response to a determination that the device is in the second status, operating the variable radio frequency amplifier with a second linearity configuration for the variable radio frequency amplifier according to the second status of the device.

5. The device of claim 4 wherein the radio frequency front-end is configured to vary the linearity configuration for the variable radio frequency amplifier corresponding to the variable status of the plurality of statuses of the device by, in response to a determination that the device is in the second status, determining whether the device is in a third status or in a fourth status of the plurality of statuses for the device.

6. The device of claim 5 wherein the third status corresponds to a situation in which no jammer is present.

7. The device of claim 6 wherein the radio frequency front-end is configured to vary the linearity configuration for the variable radio frequency amplifier corresponding to the variable status of the plurality of statuses of the device by, in response to a determination that the device is in the third status, operating the variable radio frequency amplifier with a third linearity configuration for the variable radio frequency amplifier.

8. The device of claim 7 wherein the second linearity configuration for the variable radio frequency amplifier and the third linearity configuration for the variable radio frequency amplifier are the same.

9. The device of claim 5 wherein the radio frequency front-end is configured to vary the linearity configuration for the variable radio frequency amplifier corresponding to the variable status of the plurality of statuses of the device by, in response to a determination that the device is in the fourth status, operating the variable radio frequency amplifier with a fourth linearity configuration for the variable radio frequency amplifier.

10. The device of claim 5 wherein the radio frequency front-end is configured to vary the linearity configuration for the variable radio frequency amplifier corresponding to the variable status of the plurality of statuses of the device by, testing the status of the device in a time interval to check whether the linearity configuration for the variable radio frequency amplifier shall be varied according to the status of the device.

11. The device of claim 1 wherein the device is one of a mobile phone, a tablet, a laptop, an IoT device, or a wireless-connected vehicle.

12. A method of operating a device including a variable radio frequency amplifier, comprising:
determining whether the device is in a first status or in a second status of a plurality of statuses for the device; and
based on whether the device is in the first status or the second status, varying a linearity configuration for the variable radio frequency amplifier corresponding to a variable status of a plurality of statuses of the device.

13. The method of claim 12 wherein varying the linearity configuration for the variable radio frequency amplifier corresponding to the variable status of the plurality of statuses of the device includes:
in response to a determination that the device is in the first status, operating the variable radio frequency amplifier with a first linearity configuration for the variable radio frequency amplifier according to the first status of the device.

14. The method of claim 12 wherein varying the linearity configuration for the variable radio frequency amplifier corresponding to the variable status of the plurality of statuses of the device includes:
in response to a determination that the device is in the second status, operating the variable radio frequency amplifier with a second linearity configuration for the variable radio frequency amplifier according to the second status of the device.

15. The method of claim 12 wherein varying the linearity configuration for the variable radio frequency amplifier corresponding to the variable status of the plurality of statuses of the device includes:
in response to a determination that the device is in the second status, determining whether the device is in a third status or in a fourth status of the plurality of statuses for the device.

16. The method of claim 15 wherein the third status corresponds to a situation in which no jammer is present, and varying the linearity configuration for the variable radio frequency amplifier corresponding to the variable status of the plurality of statuses of the device includes:
in response to a determination that the device is in the third status, operating the variable radio frequency amplifier with a third linearity configuration for the variable radio frequency amplifier.

17. The method of claim 12 wherein varying the linearity configuration for the variable radio frequency amplifier corresponding to the variable status of the plurality of statuses of the device includes:
testing the status of the device in a time interval to check whether the linearity configuration for the variable radio frequency amplifier shall be varied according to the status of the device.

18. The method of claim 13 wherein the device is one of a mobile phone, a tablet, a laptop, an IoT device, or a wireless-connected vehicle.

19. A variable radio frequency amplifier configured to amplify a radio frequency input signal to generate an radio frequency output signal according to a linearity configuration of a plurality of linearity configurations for the variable radio frequency amplifier, the variable radio frequency amplifier comprising a plurality of inputs, the plurality of inputs including:
a first input configured to receive the radio frequency input signal; and
a second input configured to receive a signal corresponding to a variable status of a plurality of statuses of a device.

20. The device of claim 19 wherein the device is one of a mobile phone, a tablet, a laptop, an IoT device, or a wireless-connected vehicle.
